(19) United States
(12) Patent Application Publication
(10) Pub. No.: US 2025/0209250 A1
(43) Pub. Date: Jun. 26, 2025

(54) INTEGRATED CIRCUIT DEVICE HAVING ROUTING WIRES WITH DIFFERENT WIDTH AND SHAPE FEATURES

(71) Applicant: Synopsys, Inc., Sunnyvale, CA (US)

(72) Inventors: Xu CHENG, Xiamen City (CN); Song YUAN, Xiamen Software Park (CN); Alex TSAI, Taipei City (TW)

(21) Appl. No.: 18/977,649

(22) Filed: Dec. 11, 2024

(30) Foreign Application Priority Data
Dec. 22, 2023 (WO) PCT/CN2023/140909

(51) Int. Cl. G06F 30/394

(52) U.S. Cl. CPC G06F 30/394

(57) ABSTRACT

Wiring routing for an integrated circuit may be generated by receiving a circuit design of the integrated circuit device, and determining a first routing comprising wires based on pin pairs of first pins and second pins of the circuit design. An updated routing is determined by increasing a width of a first wire of the wires to decrease a resistance of the first wire. An output routing is determined from the updated routing by adjusting a shape of the routing.

### CROSS-REFERENCE TO RELATED APPLICATION

This application claims priority to, and the benefit of PCT Application Number PCT/CN2023/140909 filed on Dec. 22, 2023, the entire content of which is hereby incorporated by reference herein in its entirety.

### TECHNICAL FIELD

The present disclosure relates to routing wires for an integrated circuit (IC) by adjusting the width and shape of the routing wires to mitigate resistance differences of the wires.

### BACKGROUND

Integrated circuit (IC) devices communicate signals to and/or from electronic devices to control the operation of the electronic devices. When designing an IC device, the routing wires are designed to reduce differences in resistances between the routing wires. Resistance differences between the routing wires can cause differences in the signals driven onto and/or received from an electronic device, negatively affecting the performance of the electronic device. In a display device, a display driver IC device is used to drive signals on to the display to control the pixels of the display device. To reduce power consumption and to reduce differences in brightness across the display device, the routing wires are designed to reduce the differences in the resistances between the routing wires. The routing wires are used to connect and drive pixels of the display device with a source voltage driven by the display device IC driver. During the design process of the display driver IC device, the routing wires are designed to reduce differences in resistances between the routing wires.

### SUMMARY

In one example, a method includes receiving a circuit design of an integrated circuit device, and determining a first routing comprising wires based on pin pairs of first pins and second pins of the circuit design. Further, the method includes determining an updated routing by increasing a width of a first wire of the wires to decrease a resistance of the first wire. The method further includes determining an output routing from the updated routing by adjusting a shape of the routing.

In one example, a system includes a memory storing instructions, and a processor, coupled with the memory and to execute the instructions. The instructions when executed cause the processor to receive a circuit design of an integrated circuit device, and determine a first routing comprising wires based on pin pairs of first pins and second pins of the circuit design. Further, processor is caused to determine an updated routing by increasing a width of a first wire of the wires to decrease a resistance of the first wire. The processor is further caused to determine an output routing from the updated routing by adjusting a shape of the routing.

A non-transitory computer readable medium comprising stored instructions, which when executed by a processor, cause the processor to receive a circuit design of an integrated circuit device, and determine a first routing comprising wires based on pin pairs of first pins and second pins of the circuit design and a width parameter. Further, the processor is caused to determine an output routing by increasing a width of the first wire of the wires to decrease a resistance of the first wire and adjusting a shape of a second wire of the wires to increase the resistance of the second wire. The processor is further caused to determine an updated circuit design based on the output routing.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates flowchart of method for determining routing in a circuit design in accordance with some embodiments of the present disclosure.

FIG. 2 illustrates a flowchart of a method for determining an initial routing in a circuit design in accordance with some embodiments of the present disclosure.

FIG. 3A illustrates a block diagram of an example integrated circuit device in accordance with some embodiments of the present disclosure.

FIG. 3B illustrates a block diagram of example pins of an integrated circuit device in accordance with some embodiments of the present disclosure.

FIG. 3C illustrates a block diagram of example pins of an integrated circuit device in accordance with some embodiments of the present disclosure.

FIG. 4 illustrates a block diagram of example routing of an integrated circuit device in accordance with some embodiments of the present disclosure.

FIG. 5 illustrates a flowchart of a method for determining an updated routing in a circuit design in accordance with some embodiments of the present disclosure.

FIG. 6 illustrates a block diagram of example routing of an integrated circuit device in accordance with some embodiments of the present disclosure.

FIG. 7 illustrates a block diagram of example routing of an integrated circuit device in accordance with some embodiments of the present disclosure.

FIG. 8 illustrates a flowchart of a method for determining an output routing in a circuit design in accordance with some embodiments of the present disclosure.

FIG. 9A illustrates a block diagram of example routing of an integrated circuit device in accordance with some embodiments of the present disclosure.

FIG. 9B illustrates a block diagram of example routing of an integrated circuit device in accordance with some embodiments of the present disclosure.

9C illustrates a portion of a block diagram of example routing of an integrated circuit device in accordance with some embodiments of the present disclosure.

FIG. 9D illustrates a block diagram of example routing of an integrated circuit device in accordance with some embodiments of the present disclosure.

FIG. 9E illustrates a block diagram of example routing of an integrated circuit device in accordance with some embodiments of the present disclosure.

FIG. 10 depicts a flowchart of various processes used during the design and manufacture of an integrated circuit in accordance with some embodiments of the present disclosure.

FIG. 11 depicts a diagram of an example computer system in which embodiments of the present disclosure may operate.

### DETAILED DESCRIPTION

Aspects of the present disclosure relate to an integrated circuit device having routing wires with different shape and width features.

Electronic devices perform various operations based on signals received from integrated circuit (IC) devices (or IC drivers). Internal circuit elements of an IC device include pins interconnected by routing wires to output signals to an electronic device. The interconnected pins may be located within driver circuitry of an IC device. During the design process, the routing wires are designed (e.g., configured or generated) to reduce differences in the resistances between the routing wires. Resistance differences between the routing wires can cause differences in the signals driven onto and/or received from an electronic device, negatively affecting the performance of the electronic device.

In one example, an electronic device is a display device and an IC device is a display driver IC (DDIC) device. The display device may be a liquid crystal display (LCD) device, a light emitting diode (LED) display device, or an organic LED (OLED) display device, among others. A display device includes multiple pixels connected to routing wires both within the display device and within the DDIC. Differences in the resistances between the routing wires generate display artifacts, including brightness differences between the pixels. The display artifacts negatively affect the performance of the display device.

During the design process, routing wires within an IC device may be manually designed. Accordingly, a common width is used to design the routing wires. As different routing wires may have different lengths, there may be a resistance difference between the routing wires. As is noted above, the resistance difference may negatively affect the performance of an electronic device. Routing the wires while mitigating resistance differences between the wires is a difficult and complex problem as the minimum resistance value that can be used to route the wires and a width of the wires used to reach a target resistance to mitigate resistance difference are unknown, and mitigating resistance differences between the routing wires is difficult. Accordingly, during the design process to mitigate resistance differences, the wires are routed with a first width and then adjusted by perming multiple iterations on each wire one by one to reach a target resistance for all of the wires. However, such a process is time consuming, and computationally complex, which increases the design time and resources used to design an IC device, and increases the manufacturing cost of the corresponding IC device.

The IC design system and method described herein generate routing wires, while mitigating differences in resistances between the wires. As is described in further detail in the following, an initial routing of the wires is generated. An adjusted routing is generated from the initial routing by varying the width of the wires based on a target resistance, reducing the resistance of the wires. Multiple iterations may be used to generate the adjusted routing. An output routing is generated from the adjusted routing by varying the length of one or more of the wires, varying the resistance of the wires and mitigating resistance differences between the wires.

Technical advantages of the present disclosure include, but are not limited to, generating a routing for an IC device where the resistance difference between wires within the routing are mitigated. The circuit design process as described herein generates a wire routing having reduced resistance differences, improving the performance of a corresponding electronic device as compared to circuit design processes that do not alter the width and length of the wires during the design process. The circuit design process described herein generates a routing having an improved local deviation (e.g., difference in resistance between adjacent wires) and/or global deviation (e.g., the difference between maximum and minimum resistance of the wires), as compared to other circuit design processes. In one more examples, the circuit design process as described herein generates the routing having a reduced resistance differences using less time and/or processing resources as compared to other circuit design processes, reducing the design cost and manufacturing cost of the IC device.

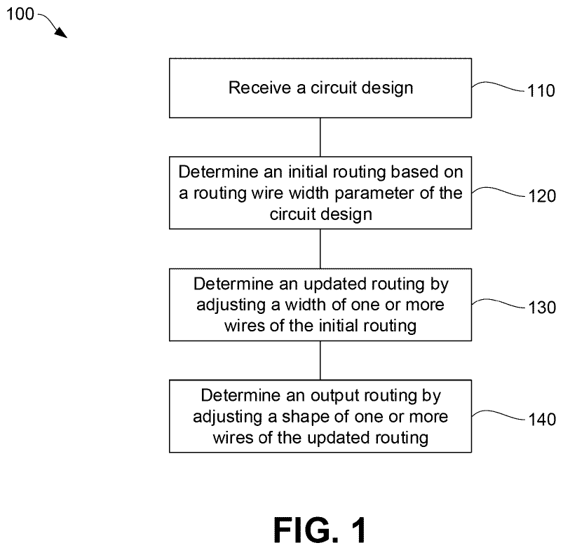

FIG. 1 illustrates a method 100 for routing wires in an IC device, according to one or more examples. In one example, the IC device is a display driver IC device that drives a display device. In other example, the IC device is a controller device, or another type of IC device that communicates signals to and from an electronic device. The electronic device can be a display device, a sensor device, or a communication device, among others.

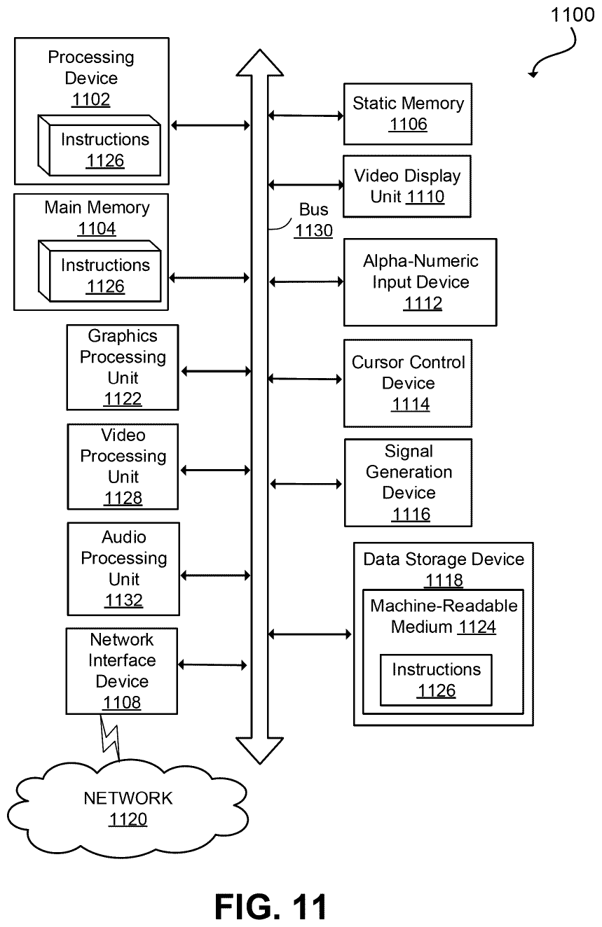

In one example, the method 100 is performed by a computer system (e.g., the computer system 1100 of FIG. 11). In one example, the computer system is a circuit design system. In one or more example, the computer system is an electronic design automation (EDA) system. The computer system includes one or more processor devices (e.g., the processing device 1102 of FIG. 11) that execute instructions (e.g., instructions 1126 of FIG. 11) stored a memory device (e.g., the main memory 1104 or machine-readable medium 1124 of FIG. 11) to perform the method 100. In the following, the method 100 is described with regard to the computer system 1100 of FIG. 11.

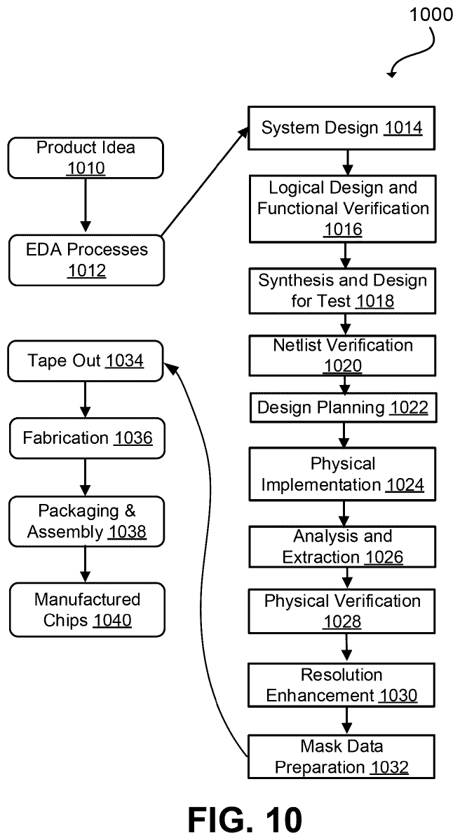

In one example, the method 100 is performed as part of design planning 1022 and/or physical implementation 1024 of FIG. 10.

At 110, a circuit design is received. The circuit design for an IC device. In one example, the IC device is a display driver device, controller device, or another type of IC device, among others. In one example, the processing device 1102 executes instructions 1126 stored in the main memory 1104 or the machine-readable medium 1124 to receive (obtain) the circuit design. The circuit design is obtained from a memory device or received from another system connected to the computer system 1100.

At 120, an initial routing is determined based on a routing wire width parameter of the circuit design. In one example, the processing device 1102 executes instructions 1126 stored in the main memory 1104 or the machine-readable medium 1124 to determine an initial routing based on a routing wire width parameter of the circuit design. The routing includes one or more wires routed between pairs of pins (e.g., ports) of the circuit design. The width parameter defines a width, or range of widths, that is used to generate the wires. In one example, generating the routing includes determining a width and a routing direction for each of the wires to connect respective pin pairs.

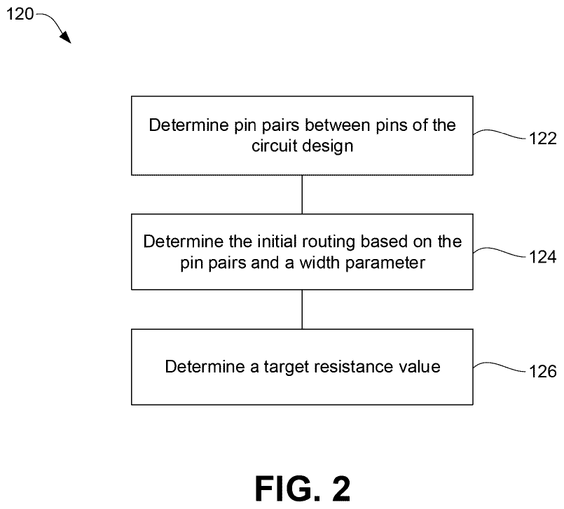

In one example, generating the initial routing of 120 includes determining pin pairs and a range of width values as illustrated in 122 of FIG. 2. In one example, the processing device 1102 determines the pin pairs from the circuit design. In another example, the pin pairs are determined based on a pin pair design file stored within and obtained from a main memory 1104 and/or machine-readable medium 1124 by the processing device 1102. In one example, coupling pin pairs includes coupling (e.g., electrically coupling) a pin of a first group of pins with a pin of second group of pins.

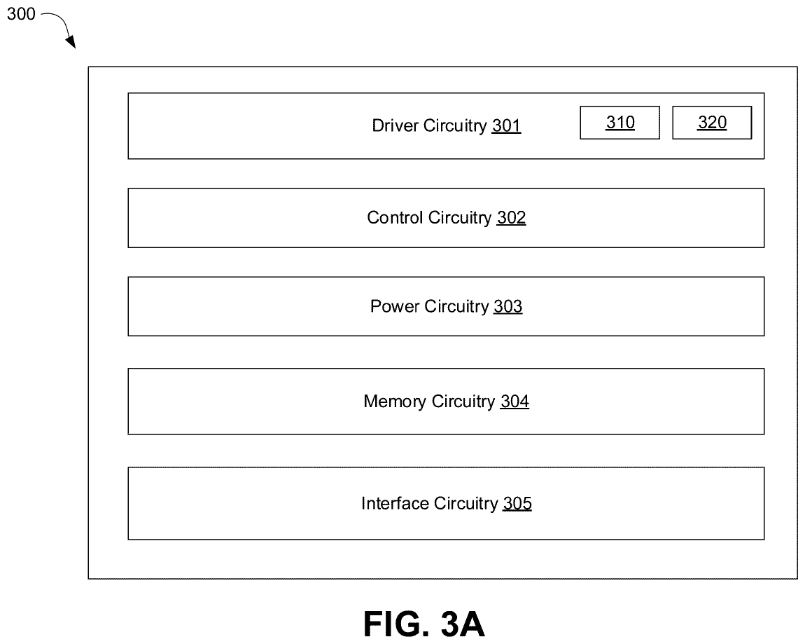

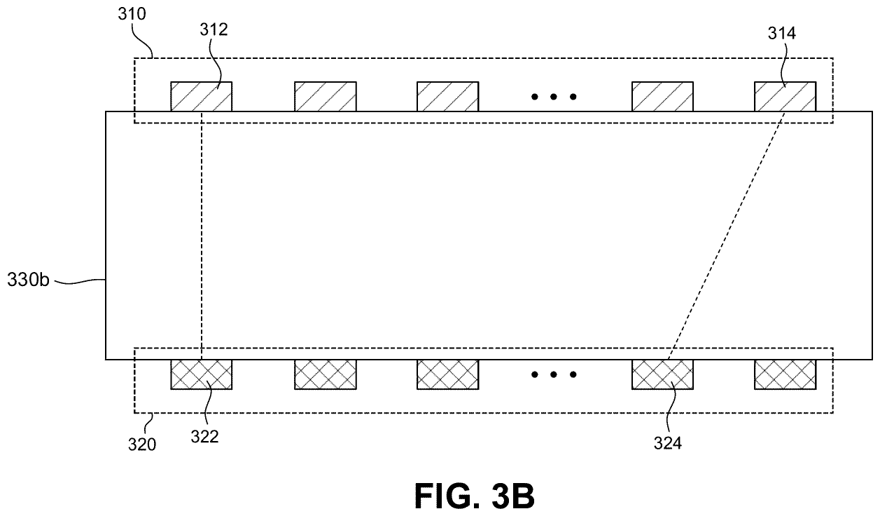

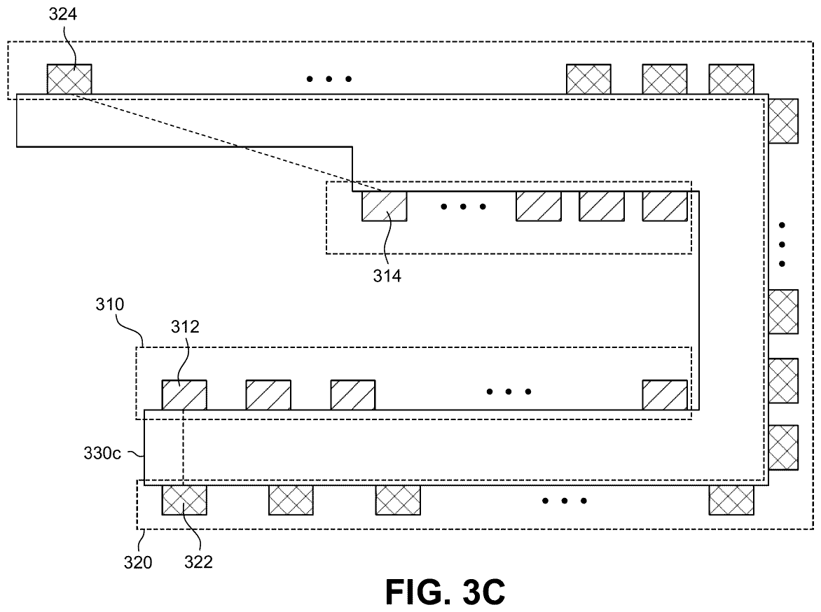

FIG. 3A illustrates an example IC device 300. The IC device 300 includes driver circuitry 301, control circuitry 302, power circuitry 303, memory circuitry 304, and interface circuitry 305. In other examples, the IC device 300 includes other types of circuitry and/or omits one or more of the circuitry elements illustrated in FIG. 3. In one example, the driver circuitry 301 drives data signals and/or control signals, among other signal types onto an electronic device coupled to the IC device 300. In an example where the IC device 300 is a DDIC device, the driver circuitry 301 includes display panel driver circuitry and data driver output circuitry that are configured to drive display data signals and control signals (e.g., timing signals) onto a display device to control updating the display device.

The driver circuitry 301 includes pins 310 and pins 320. In one example, the pins 310 are coupled to the pins 320, providing a communication pathway for signals to be communicated out of the driver circuitry 301. The pins 310 are associated with first circuit elements of the driver circuitry 301, and are output pins. The pins 320 function as the output of the driver circuitry 301 and receive signals from the pins 310. The pins 320 are the output pins of the IC device 300 or are coupled to output pins of the IC device 300. In one example, the configuration of the pins 310 differs from that of the pins 320. For example, the pitch of the pins 320 may be greater than the pitch of the pins 310, or the location of one or more of the pins 320 may be offset from the location of the pins 310. In other examples, other configurations may be used for the pins 320 relative to the pins 310. The configuration may correspond to the circuit design defining the location of circuit elements of the display driver relative to each other. The routing as is described in the following is used to couple pairs of the pins 310 and 320.

The control circuitry 302 determines the data and control signals driven onto an electronic device. The control circuitry 302 is coupled to the driver circuitry 301 and outputs the data and the control signals to the driver circuitry 301. In an example where the IC device 300 is a DDIC device, the control circuitry 302 includes image processing circuitry, and timing controller circuitry, among others.

The power circuitry 303 generates one or more power signals used by the other elements of the IC device 300. The memory circuitry 304 stores local data for the IC device 300. The interface circuitry 305 communicates signals (e.g., data signals, control signals, and/or clock signals, among others) to other IC devices connected to the IC device 300.

FIG. 3B illustrates a configuration of the pins 310 and pins 320. In one example, the pins 310 and the pins 320 include one or more pins. In one example, the pins 310 and the pins 320 include the same number of pins. In other examples, the pins 310 include more or less pins than the pins 320. A pin pair includes a pin of pins 310 and a pin of pins 320. In one example, the processing device 1102 determines that the pin 312 of the pins 310 and that the pin 322 of the pins 320 are a first pin pair based on the parameters of the circuit design of the IC device 300 or a pin pair design file. Further, the processing device 1102 determines that the pin 314 of the pins 310 and that the pin 324 of the pins 320 are a second pin pair. The processing device 1102 further determines pin pairs for the remaining pins of pins 310 and 320. The pin pairs are saved to a memory device (e.g., the main memory 1104 or machine-readable medium 1124). In one example, the distance between the pins 312 and 322 is less than the distance between the pins 314 and 324.

In one example, the pins 310 and 320 are separated by a routing region 330b. The routing region 330b is the region where the routing wires are placed (disposed). In one example, the positioning of the routing wires is limited such that the routing wires cannot be placed outside the routing region 330b.

FIG. 3C illustrates an alternative configuration for the pins 310 and 320. As is illustrated in FIG. 3C, the pins 310 are disposed along an inner parameter of the routing region 330c, and the pins 320 are disposed along an outer parameter of the routing region 330c. FIGS. 3B and 3C illustrate two example configurations for the routing region 330, and in other examples, the routing region 330 may have other configurations.

With further reference to FIG. 2, determining the initial routing of 120 includes 124, determining the initial routing based on the pins pairs and a width parameter. In one example, the processing device 1102 accesses a memory device to obtain a width parameter. The width parameter includes a width values for the routing wires. The width values include a minimum width value and a maximum width value. The width values may include width values between the minimum and maximum width value. In one example, as the distances between the pin pairs may differ, the length of the wires within the routing difference from each other. Accordingly, as the wires have the same width, the resistance of the wires differs from each other.

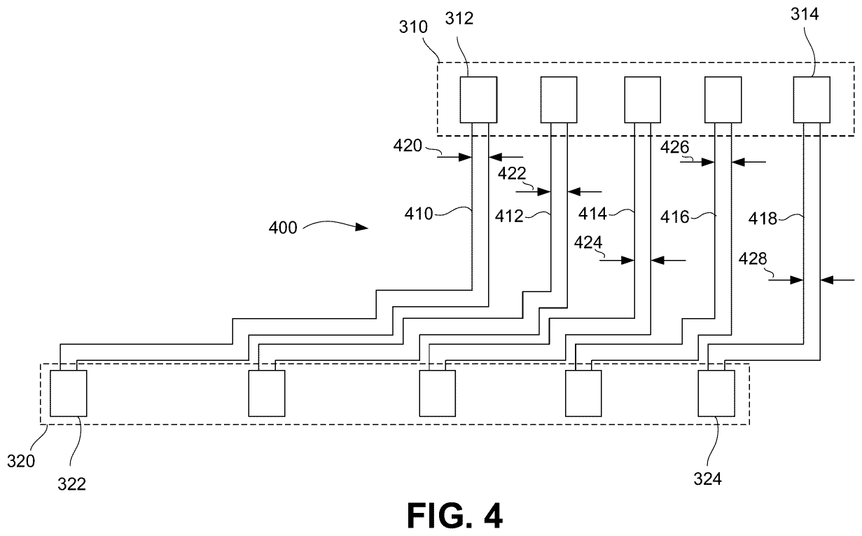

FIG. 4 illustrates the pins 310 coupled to the pins 320 via routing 400. In one example, the processing device 1102X obtains the width parameter and pin pairs from the main memory 1104, and determines the routing 400 between the pin pairs based on a width value of the width parameter. The processing device 1102 routes the wires 410-418 to couple respective ones of the pins 310 and the pins 320 (e.g., the pin pairs) based on the width parameter. For example, the pin 312 is coupled to the pin 322 via the wire 410, and the pin 314 is coupled to the pin 324 via the wire 418. In one example, the processing device 1102 determines the wires 410-418 having a respective width 420-428 based on a width value determined from the width parameter. A common width value is used for each of the wires. Accordingly, the widths 420-428 are the same.

With further reference to FIG. 2, determining the initial routing of 120 includes 126, determining an initial target resistance value. The processing device 1102 determines the initial target resistance based on the resistance values of the wires within the initial routing. In one example, the routing lengths of at least two of the wires within the initial routing differ from each other. Accordingly, the resistance differs between the wires having a different routing length. In one example, the processing device 1102 determines the initial target resistance value from the resistances of the wires of the routing. The processing device 1102 determines a resistance for each of wires based on the width and corresponding routing length of the wires. In one example, a maximum resistance value is determined from the resistances of the wires, and the initial target resistance value is set based on the maximum resistance. In another example, the processing device 1102 determines the minimum resistance value, and sets the initial target resistance to be a resistance value that is less than the maximum resistance value.

With reference to FIG. 4, the processing device 1102 determines resistance value for each of the wires 410-418, based on a respective one of the widths 420-428, and a respective length of the wires 410-418. In one example, the widths 420-428 are the same. In such an example, the resistance value of the wire 410 is greater than that of the other wires 412-418, as the length of the wire 410 is greater than that of the other wires 412-418. The processing device 1102 sets the initial target resistance to be the highest resistance value of the wire 400. In one example, the wire 400 is determined to have the highest (or maximum) resistance value, and the initial target resistance is set to the resistance value of the wire 410. In another example, the processing device 1102 sets the initial target resistance to be a resistance value of the wires 400 other than the highest resistance value.

The initial target resistance is stored in a memory device (e.g., the main memory 1104 and/or machine-readable medium 1124 of FIG. 11). Further, the initial routing is stored in a memory device (e.g., the main memory 1104 and/or machine-readable medium 1124 of FIG. 11).

With further reference to FIG. 1, the method 100 includes 130, determining an updated routing by adjusting a width of one or more wires of the initial routing. For example, the processing device 1102 obtains the initial routing from the memory device. The processing device 1102 increases the width of one or more wires, decreasing the resistance of the adjusted wire or wires. The processing device 1102 adjusts the width of the one or more wires to decrease a difference in resistance of the wires. In one example, the width of a wire is increased to decrease the resistance of the wire. With reference to FIG. 4, the width of one or more of the wires 410-418 is increased, decreasing the resistance of the one or more wires 410-418. For example, the width of the wire 410 is increased, decreasing the resistance of the wire 410. As the wire 410 had the largest resistance, decreasing the resistance of the wire 410, decreasing the difference in resistance between the wire 410, and the wires 412-418. In other examples, the width of one or of the wires 412-418 is adjusted (e.g., increased), to decrease the resistance of the corresponding wire. In one example, the widths of two or more of the wires 410-418 are adjusted during non-overlapping periods. In another example, the widths of two or more of the wires 410-418 are adjusted during at least partially overlapping periods.

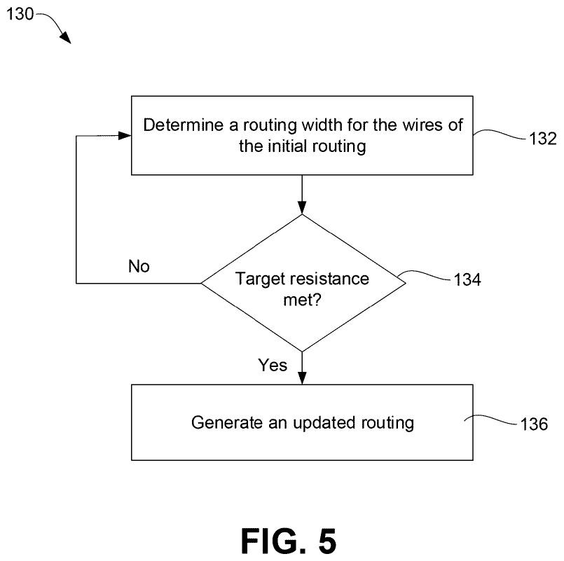

In one example, determining an updated routing by adjusting a width of one or more wires of the initial routing includes 132 of FIG. 5, calculating the routing width for the wires of the initial routing. In example, the processing device 1102 adjusts the width of one or more wires 410-418 of FIG. 4, to decrease a resistance of the wires. The widths of the wires 410-418 are adjusted, reducing the initial target resistance.

In one example, the processing system 1102 determines a target resistance use to route the wires 410-418. The target resistance is determined such that the parameters of the circuit design are satisfied. In one example, the target resistance is the smallest possible resistance that can be used to route the wires. In other examples, the target resistance can have other values as along as the parameters of the circuit design are satisfied. In one example, the processing device 1102 determines a resistance range [Rₘᵢₙ, Rₘₐₓ] based on the widths. The processing device 1102 sets the resistance range [Rₘᵢₙ, Rₘₐₓ] to be equal [0, Rᵢₙᵢₜᵢₐₗ]. In one example, multiple interactions are used to determine the width of the wires. In one example, the processing device 1102 uses a dichotomy method to decrease the resistance of the wires. For a first iteration, the resistance

$$\overline{R} = \frac{{R}_{min} + {R}_{max}}{2}$$

is used to route the wires 410-418. At 134, a determination as to whether or not the resistance of the wires 410-418 meets the target resistance. If the target resistance is determined to not be met at 134, the minimum resistance Rₘᵢₙ is set to R̅, such that Rₘᵢₙ=R̅, and the method returns to 132. If the target resistance is determined to be met at 134, the maximum resistance, Rₘₐₓ, is set to R̅, such that Rₘₐₓ=R̅. 132 and 134 of FIG. 5 are repeated (iterated) until the target resistance is met by increasing the width of the wires 410-418 of the routing 400. Meeting the target resistance includes satisfying (e.g., meeting) the condition all wires being able to be routed successfully and the resistance of all wires being smaller or equal to the current target resistance. In one example, the width of the wires is adjusted based on the width value range of the corresponding width parameter.

The global deviation D_{global} (e.g., the difference between the maximum and minimum resistances in wires) is mitigated by increasing the widths of the wires of the routing.

The resistance of a wire can be determined based on equation 1.

$$R = ρ ( \frac{l}{w} - {n}_{j o g} {d}_{c o r} ) \qquad Equation 1$$

The width of a wire can be determined based on equation 2.

$$w = \frac{l}{\frac{R}{ρ} + {n}_{j o g} {d}_{c o r}} \qquad Equation 2$$

In equation 2, ρ is sheet resistance, l is wire length, w is wire width, n_{jog} is number of wire corners, d_{cor} is corner ratio, R is target resistance. A wire corner is where a wire changes directions.

The width of each wire is determined based on the width range for the wires as illustrated in equation 3.

$${w}^{′} = MIN ( MAX ( w , {w}_{min} ) , {w}_{max} ) \qquad Equation 3$$

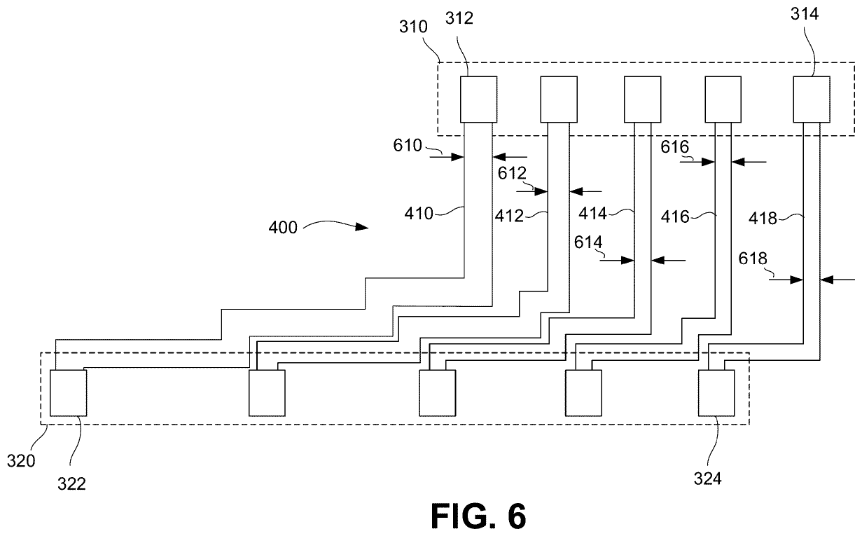

FIG. 6 illustrates the wires 410-418 with adjusted widths. As is illustrated in FIG. 6, the width 610 of the wire 410 is greater that the widths 612-618 of the wires 412-418. Further, the width 612 of the wire 612 has is greater than the widths 614-618 of the wires 414-418. In one example, the widths 414-418 are the same. In other examples, one or more widths 614-618 differ from another one of the widths 614-618. In one example, the adjusted widths are stored within a memory device (e.g., the main memory 1104 and/or the machine-readable medium 1124 of FIG. 11).

In one or more examples, wires having a lower resistance, have a larger width and use more area than wires having a higher resistance. In one example, a final target resistance is in the range of [Rₘᵢₙ, Rₘₐₓ]. In such an example, a resistance of a first iteration used to determine the wire widths is set to

$${R}_{target} = \frac{{R}_{min} + {R}_{max}}{2} .$$

If all wires can be routed and the resistances are smaller or equal to R_{target}, the final target resistance is determined to be in the range of [Rₘᵢₙ, R_{target}], and operation is repeated (e.g., another iteration is performed). If not all wires can be routed or some resistances are larger than R_{target}, then the final target resistance is in the range of [R_{target}, Rₘₐₓ], and the operation is repeated (e.g., another iteration is performed).

In one example, a routing includes m wires, the length of wire i is lᵢ, the Job of wire i is n_{jog}_{ᵢ}, the width range of the wires is [wₘᵢₙ, wₘₐₓ]. The width of wire i after the iteration n is wᵢ_{ₙ}, the resistance of wire i after the iteration n is Rᵢ_{ₙ}, the target resistance in the iteration n is R_{target}_{ₙ}, and the resistance range after the iteration n: [Rₘᵢₙ_{ₙ}, Rₘₐₓ_{ₙ}] (before the first iteration [Rₘᵢₙ_{ₒ}, Rₘₐₓ_{ₒ}]=[0, Rᵢₙᵢₜᵢₐₗ]). Wire width may be determined using equation 4. The equation 4 is a combination of the equations 2 and 3.

$${w}_{{i}_{n}} = MIN ( MAX ( w = \frac{{l}_{i}}{\frac{{R}_{{target}_{n}}}{ρ} + {n}_{{jog}_{i}} {d}_{cor}} , {w}_{min} ) , {w}_{max} ) \qquad Equation 4$$

In one example, there are m wires, the resistance range before a first iteration is [Rₘᵢₙ_{ₒ}, Rₘₐₓ_{ₒ}]=[0, Rᵢₙᵢₜᵢₐₗ], and the target resistance for the first iteration is

$${R}_{{target}_{1}} = \frac{{R}_{{min}_{0}} + {R}_{{max}_{0}}}{2} = \frac{{R}_{i n i t i a l}}{2} .$$

The width for each of the wires wᵢ_{ₙ} is determined based on the equation 4, and the routing is repeated. In iteration 1, if all wires routed successfully, and the resistances of all of the wires are smaller or equal to the iteration 1 target resistance (Rᵢ_{₁}≤R_{target}_{₁}, i=1, 2, 3, . . . , m), the minimum and maximum resistances are determined

$$[ {R}_{min} , {R}_{{max}_{1}} ] = [ {R}_{{min}_{0}} , {R}_{{target}_{1}} ] = [ 0 , \frac{{R}_{i n i t i a l}}{2} ] .$$

If some wires are routed unsuccessfully or some wires' resistances are larger than R_{target}_{₁}, the minimum and maximum resistances are determined as

$$[ {R}_{min} , {R}_{{max}_{1}} ] = [ {R}_{{target}_{1}} , {R}_{{max}_{1}} ] = [ \frac{{R}_{i n i t i a l}}{2} , {R}_{initial} ] .$$

For a following iteration (e.g., iteration n+1), the maximum and minimum resistances before iteration n+1 are [Rₘᵢₙ_{ₙ}, Rₘₐₓ_{ₙ}], and the target resistance in the iteration n+1:

$${R}_{{target}_{n + 1}} = \frac{{R}_{{min}_{n}} + {R}_{{max}_{n}}}{2} .$$

The width for all the wires wᵢ_{ₙ} is determined using equation 4 and routing of the wires is repeated. If all wires routed successfully, and the resistances of all of the wires are determined to smaller or equal to the iteration n target resistance, that is (Rᵢ_{ₙ}≤R_{target}_{ₙ}, i=1, 2, 3, . . . , m), the minimum and maximum resistances are determined as [Rₘᵢₙ_{ₙ₊₁}, Rₘₐₓ_{ₙ₊₁}]=[Rₘᵢₙ_{ₙ}, R_{target}_{ₙ₊₁}]. If some wires are routed unsuccessfully or some wires' resistances are larger than R_{target}_{ₙ₊₁}, the minimum and maximum resistances are determined as Rₘᵢₙ_{ₙ₊₁}, Rₘₐₓ_{ₙ₊₁},=[R_{target}_{ₙ₊₁}, Rₘₐₓ_{ₙ₊₁}].

In an example where the final target resistance is R_{target}_{_{final}}, after n iterations, the error between R_{target}_{ₙ} and R_{target}_{_{final}} can be further reduced to be smaller or equal to

$$\frac{{R}_{i n i t i a l}}{{2}^{n}} .$$

Accordingly, for more iterations completed, the error is reduced in value. For example, if Rᵢₙᵢₜᵢₐₗ is 1000 ohm, up to 10 iterations may be needed confirm that the error is smaller or equal than 1 ohm.

In one example, 132 and 134 of FIG. 5 are iterated (completed) until the error is determined to be less than or equal to a threshold value. The threshold may be provided as a parameter of the circuit design. In one example, the error is one or more ohms. In one example, if the final iteration k satisfies the condition where all wires can be routed successfully, and the resistances of all of the wires is determined to smaller or equal to the iteration k target resistance of (Rᵢ_{ₖ}≤R_{target}, i=1, 2, 3, . . . , m), the resistance value R_{target}_{ₖ} is set as the target resistance. Further, the routing result is set as the updated routing determined at 136. If the final iteration k doesn't satisfy the condition, the condition where all wires can be routed successfully, and the resistances of all of the wires are smaller or equal to the iteration k target resistance, Rₘₐₓ_{_{k−1}} is set as the target resistance and routing result using target resistance Rₘₐₓ_{_{k−1}} is set as the updated routing at 136.

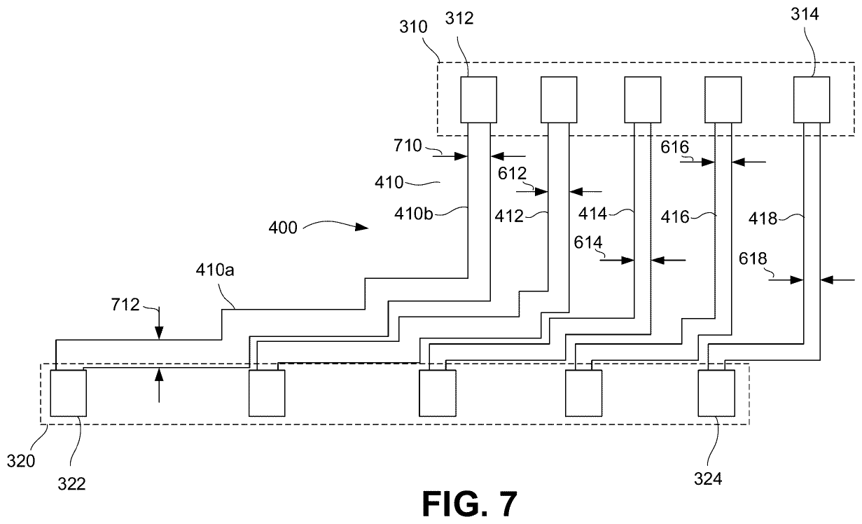

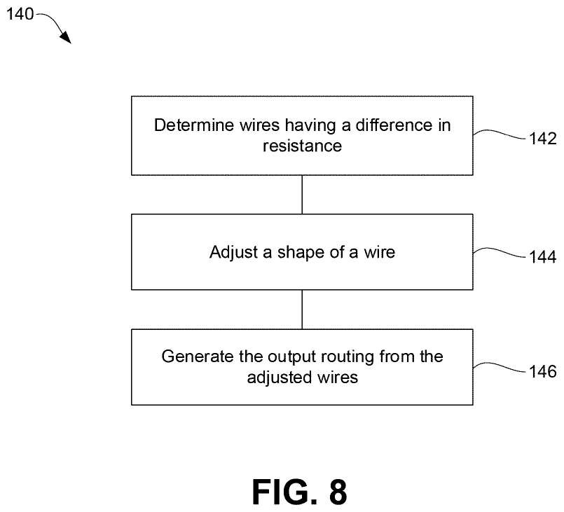

In one or more example, adjusting the resistance of a wire 410-418 includes partitioning (e.g., dividing) a wire into two or more segments. The width of a first segment of a wire is adjusted independently from another segment of the wire. Accordingly, the segments have a different widths. For example as is illustrated in the example of FIG. 7, the wire 410 includes segments 410a and 410b. The width 712 of the segment 410a differs from the width 710 of the segment 410b. In one example, the width 712 is greater than the width 710. In other examples, the width 710 is greater than the width 712. Further, while FIG. 7 includes two segments 410a and 410b, in other examples, the wire 410 may include more than two segments, each having different widths. In other examples, one or more of the wires 412-418 include multiple segments, the segments having different widths. In one example, a wire is partitioned into multiple segments having different widths when adjusting the width of the entire wire is not able to meet the target resistance.

In one example, the width of the first segment (part) of a wire is w₁, and the width of the second segment of the wire is w₂. In such an example, w₁ is less than or greater than w₂. The resistance of the first segment is R₁, the length of second segment is l₂ the jogs are n_{2jog}. The width w₂ is determined based on equation 5.

$${w}_{2} = \frac{{l}_{2}}{\frac{R - {R}_{1}}{ρ} + {n}_{2 j o g} {d}_{c o r}} \qquad Equation 5$$

The width w′₂ that is used to route the wire is determined from equation 6.

$${w}_{2}^{′} = MIN ( MAX ( {w}_{2} , {w}_{min} ) , {w}_{max} ) \qquad Equation 6$$

At 136, the updated routing is determined. The processing device 1102 determines the updated routing from the adjusted widths determined during 132 and 134. The updated routing is stored in the memory device.

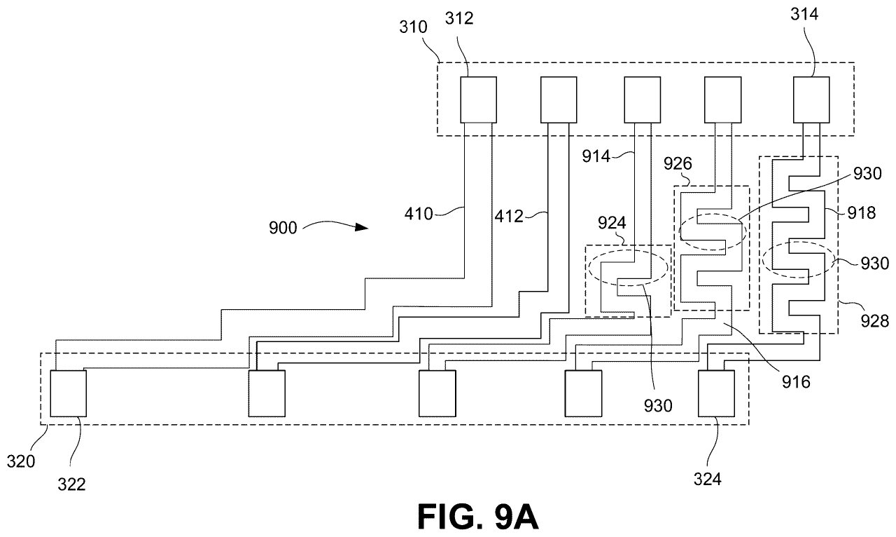

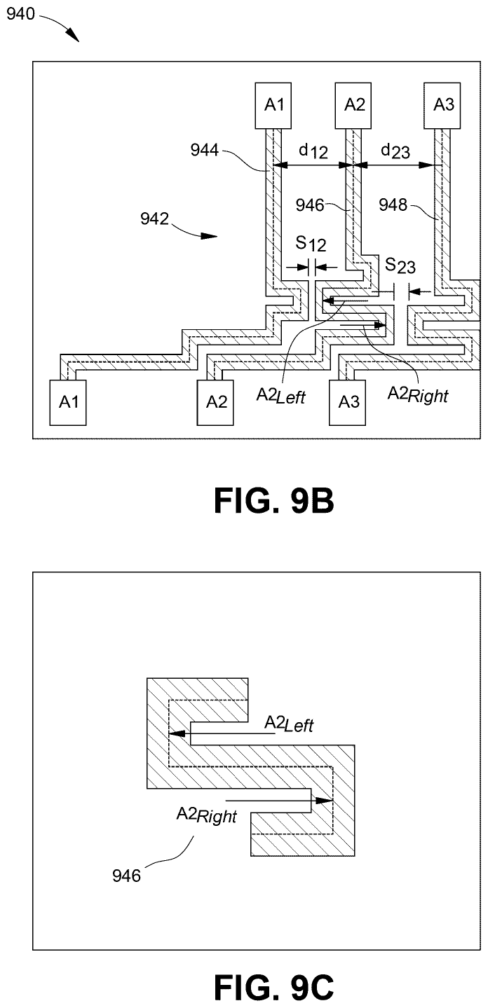

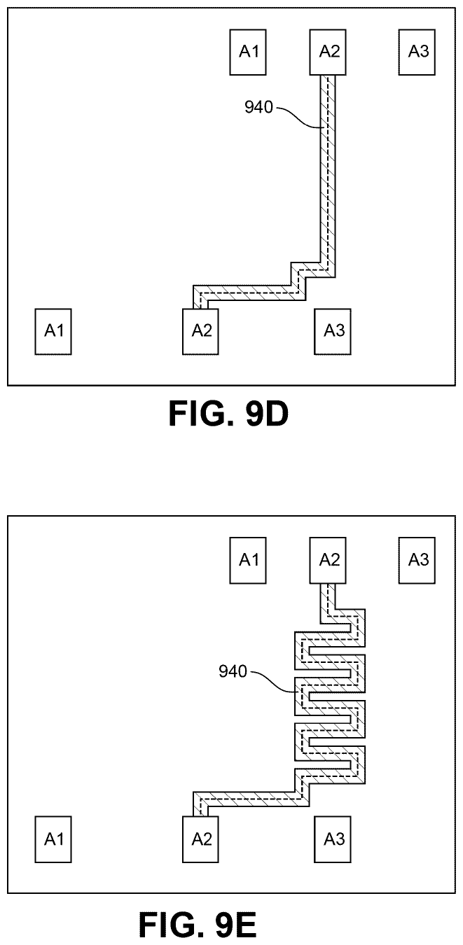

At 140, an output routing is determined by adjusting a shape of one more of the wires of the updated routing. In one example, the processing device 1102 obtains the updated routing from a memory device and adjusts the shape of one or more of the wires to reduce a difference in resistance between two or more of the wires to determine an output routing. In one example, the processing device 1102 determines that two or more of the wires of the routing have a difference in resistance at 142 of FIG. 9. With reference to FIG. 5, the processing device 1102 determines a resistance of each of the wires 410-418. The resistance is determined based on the widths of the wires and the lengths of the wires. Based on the resistance, the processing device 1102 determines that two or more of the wires 410-418 have a difference in resistance.

In one example, the processing device 1102 determines a resistance range [Rᵢ_{ₘᵢₙ}, Rᵢ_{ₘₐₓ}], for each wire 410-418. Rᵢ_{ₘᵢₙ} is the minimum resistance of a wire i with non-linear segments, and Rᵢ_{ₘₐₓ} is the max resistance of a wire i having a non-linear segment. Example, non-linear segments are illustrated in FIG. 9. As is illustrated in FIG. 9, the routing 900 has wires 410, 412, 914, 916, and 918. As compared to the routing 400 of FIG. 4, the routing 900 includes one more wires having a non-linear segment. For example, the wires 814, 916, and 918 each include non-linear segments 924, 926, and 928, respectively. While the non-linear segments 924-928 are illustrated as having a square waveform shape, in other examples, a linear segment may have a sinusoidal shape, triangular shape, and/or a sawtooth shape, among others. Further, the shape of one or more of the segments 924-928 may differ from the shape of another one or more segment 924-928. The non-linear segments 924-928 include oscillations that form the corresponding shape of the non-linear segments. The non-linear segments 924-928 is along the path of a corresponding wire. In one or more examples, the number of oscillations along a path of a wire may differ between the non-linear segments 924-928. For example, the non-linear segment 928 includes more oscillations that the non-linear segment 926, which has more oscillations than the non-linear segment 924. In one example, at least two non-linear segments 924-828 have the same number of oscillations 930.

At 144 of 140, a shape of a wire is adjusted. Adjusting a wire to include non-linear segments increases the resistance of the corresponding wire as the length of the wire is increased. In one example, the paths of the wires are adjusted to include non-linear segments to mitigate differences in resistance between the wires. Equation 6 may be used to determine the length, and the number of oscillations of a non-linear segment to include in a wire.

$$min ( {\sum }_{i = 2}^{n} \sqrt{1 + {( {R}_{i} - {R}_{i - 1} )}^{2}} ) \qquad Equation 7$$

In Equation 7, Rᵢ (Rᵢ∈[Rᵢ_{ₘᵢₙ}, Rᵢ_{ₘₐₓ}]) is resistance of wire i. In one example, after calculating the target resistance of each wire Rᵢ and the resistance gap Rᵢ−Rᵢ_{ₘᵢₙ}, the resistance for each wire can be compensated by adding different number oscillations of a non-linear region to reduce the differences in resistances between the wires. In one example, the shape of wire having a lower resistance than another wire is adjusted to include a non-linear region having one or more oscillations. In one example, a non-linear region that includes more oscillations is larger than a non-linear region that has a smaller number of oscillations. By increasing the number oscillations, e.g., the size of the non-linear region, the resistance of a wire is increased. The number of oscillations, e.g., the size of the non-linear region, is increased to reduce differences in resistances between wires, e.g., increase the resistance of a wire relative to another wire.

In one example, after the widths of the wires are determined, and the minimum resistance of each wire (e.g., Rᵢ_{ₘᵢₙ}), and final target resistance Rᵢ are determined, the resistance of a square wave unit (turn) is determined as rt. Based on the number of square wave units used to form a wire, (Rᵢ−Rᵢ_{ₘᵢₙ})/rᵢ is determined.

FIG. 9B illustrates routing 940. The routing 940 includes wires 942. In FIG. 9B, the center line distance between wires 944 and 946 and A2 is d₁₂, the center line distance between 946 and 948 is d₂₃, width of wire i is wᵢ, min spacing between 944 and 946 is s₁₂, and min spacing between 946 and 948 is s₂₃. Further, the left amplitude

$$A {2}_{left} = \frac{{d}_{12} - {s}_{12} - \frac{{w}_{1}}{2} - \frac{{w}_{2}}{2}}{2} ,$$

and the right amplitude of 946 is

$$A {2}_{right} = \frac{{d}_{23} - {s}_{23} - \frac{{w}_{2}}{2} - \frac{{w}_{3}}{2}}{2} .$$

FIG. 9C illustrates a square wave unit of the wire 946 having the left amplitude A2_{left} and the right amplitude A2_{right}. In FIG. 9D, the resistance for the wire 650 has a minimum value and set as Rᵢ_{ₘᵢₙ}. The wire 650 includes zero square wave units. In FIG. 9E, the resistance for the wire 650 has a maximum value and is set to Rᵢ_{ₘₐₓ}. The wire 650 includes 3.5 square wave units. In one example for the wire 650, the adjusted resistance ranges from 0 square wave units to 3.5 square wave units. In one example, if the minimum resistance of a wire is 5 ohm and the maximum resistance is 10 ohm, one square wave unit is 1 ohm. For a final target resistance of 7.5 ohm, a wire can be updated to have 2.5 square wave units, having a resistance of 7.5 ohm. For a final target resistance is 4 ohm, a corresponding wire contains 0 square wave units having a resistance of 5 ohms. For a final target resistance 11 ohm, a wire includes 5 square wave units, having a resistance of 10 ohm.

At 146 of 140, an output routing is determined from the adjusted wires. The processing device 1102 determines an output routing having one or more wires with an adjusted shape determined at 144. The output routing is stored in a memory device.

In one example, an IC device is manufactured using the output routing. For example, an updated circuit design is determined form the output routing, and the updated circuit design is used to manufacture an IC device.

FIG. 10 illustrates an example set of processes 1000 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1010 with information supplied by a designer, information which is transformed to create an article of manufacture that uses a set of EDA processes 1012. When the design is finalized, the design is taped-out 1034, which is when artwork (e.g., geometric patterns) for the integrated circuit is sent to a fabrication facility to manufacture the mask set, which is then used to manufacture the integrated circuit. After tape-out, a semiconductor die is fabricated 1036 and packaging and assembly processes 1038 are performed to produce the finished integrated circuit 1040.

Specifications for a circuit or electronic structure may range from low-level transistor material layouts to high-level description languages. A high-level of representation may be used to design circuits and systems, using a hardware description language (‘HDL’) such as VHDL, Verilog, System Verilog, SystemC, MyHDL or Open Vera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 10. The processes described by be enabled by EDA products (or EDA systems).

During system design 1014, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1016, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1018, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1020, the netlist is checked for compliance with timing constraints and for correspondence with the HDL code. During design planning 1022, an overall floor plan for the integrated circuit is constructed and analyzed for timing and top-level routing.

During layout or physical implementation 1024, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1026, the circuit function is verified at the layout level, which permits refinement of the layout design. During physical verification 1028, the layout design is checked to ensure that manufacturing constraints are correct, such as DRC constraints, electrical constraints, lithographic constraints, and that circuitry function matches the HDL design specification. During resolution enhancement 1030, the geometry of the layout is transformed to improve how the circuit design is manufactured.

During tape-out, data is created to be used (after lithographic enhancements are applied if appropriate) for production of lithography masks. During mask data preparation 1032, the ‘tape-out’ data is used to produce lithography masks that are used to produce finished integrated circuits.

A storage subsystem of a computer system (such as computer system 1100 of FIG. 11) may be used to store the programs and data structures that are used by some or all of the EDA products described herein, and products used for development of cells for the library and for physical and logical design that use the library.

FIG. 11 illustrates an example machine of a computer system 1100 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1100 includes a processing device 1102, a main memory 1104 (e.g., read-only memory (ROM), flash memory, dynamic random access memory (DRAM) such as synchronous DRAM (SDRAM), a static memory 1106 (e.g., flash memory, static random access memory (SRAM), etc.), and a data storage device 1118, which communicate with each other via a bus 1130.

Processing device 1102 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1102 may also be one or more special-purpose processing devices such as an application specific integrated circuit (ASIC), a field programmable gate array (FPGA), a digital signal processor (DSP), network processor, or the like. The processing device 1102 may be configured to execute instructions 1126 for performing the operations and steps described herein.

The computer system 1100 may further include a network interface device 1108 to communicate over the network 1120. The computer system 1100 also may include a video display unit 1110 (e.g., a liquid crystal display (LCD) or a cathode ray tube (CRT)), an alphanumeric input device 1112 (e.g., a keyboard), a cursor control device 1114 (e.g., a mouse), a graphics processing unit 1122, a signal generation device 1116 (e.g., a speaker), graphics processing unit 1122, video processing unit 1128, and audio processing unit 1132.

The data storage device 1118 may include a machine-readable storage medium 1124 (also known as a non-transitory computer-readable medium) on which is stored one or more sets of instructions 1126 or software embodying any one or more of the methodologies or functions described herein. The instructions 1126 may also reside, completely or at least partially, within the main memory 1104 and/or within the processing device 1102 during execution thereof by the computer system 1100, the main memory 1104 and the processing device 1102 also constituting machine-readable storage media.

In some implementations, the instructions 1126 include instructions to implement functionality corresponding to the present disclosure. While the machine-readable storage medium 1124 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1102 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
receiving a circuit design of an integrated circuit device;
determining a first routing comprising wires based on pin pairs of first pins and second pins of the circuit design;
determining an updated routing by increasing a width of a first wire of the wires to decrease a resistance of the first wire; and
determining, by a processor, an output routing from the updated routing by adjusting a shape of the routing.

2. The method of claim 1, wherein determining the updated routing comprises comparing the decreased resistance of the first wire to a target resistance, and determining the updated routing based on the decreased resistance meeting the target resistance.

3. The method of claim 1, wherein the width of the first wire is greater than a width of a second wire of the wires.

4. The method of claim 1, wherein determining the updated routing comprises increasing a width of a second wire of the wires to decrease a resistance of the second wire.

5. The method of claim 1, wherein determining the output routing from the updated routing by adjusting the shape of the routing, comprises determining a resistance of the first wires.

6. The method of claim 5, wherein adjusting the shape of the routing comprises determining that a resistance of a second wire of the wires is less than the resistance of the first wire, and adjusting the shape of the second wire to increase the resistance of the second wire.

7. The method of claim 6, wherein the adjusting the shape of the second wire includes determining along a path of the second wire.

8. The method of claim 7, wherein a size of the non-linear region is selected to yield the increased resistance of the second wire.

9. The method of claim 1, further comprising updating the circuit design based on the output routing.

10. A system comprising:
a memory storing instructions; and
a processor, coupled with the memory and to execute the instructions, the instructions when executed cause the processor to:
receive a circuit design of an integrated circuit device;
determine a first routing comprising wires based on pin pairs of first pins and second pins of the circuit design;
determine an updated routing by increasing a width of a first wire of the wires to decrease a resistance of the first wire; and
determine an output routing from the updated routing by adjusting a shape of the routing.

11. The system of claim 10, wherein determining the updated routing comprises comparing the decreased resistance of the first wire to a target resistance, and determining the updated routing based on the decreased resistance meeting the target resistance.

12. The system of claim 10, wherein the width of the first wire is greater than a width of a second wire of the wire.

13. The system of claim 10, wherein determining the updated routing comprises increasing a width of a second wire of the wires to decrease a resistance of the second wire.

14. The system of claim 10, wherein determining the output routing from the updated routing by adjusting the shape of the routing, comprises determining a resistance of the first wires.

15. The system of claim 14, wherein adjusting the shape of the routing comprises determining that a resistance of a second wire of the wires is less than the resistance of the first wire based on the resistances, and adjusting the shape of the second wire to increase the resistance of the second wire.

16. The system of claim 15, wherein the adjusting the shape of the second wire includes determining along a path of the second wire.

17. The system of claim 16, wherein a size of the non-linear region corresponds to the resistance of the second wire.

18. The system of claim 16, further comprising updating the circuit design based on the output routing.

19. A non-transitory computer readable medium comprising stored instructions, which when executed by a processor, cause the processor to:
receive a circuit design of an integrated circuit device;
determine a first routing comprising wires based on pin pairs of first pins and second pins of the circuit design and a width parameter;
determine an output routing by increasing a width of the first wire of the wires to decrease a resistance of the first wire and adjusting a shape of a second wire of the wires to increase the resistance of the second wire; and
determine an updated circuit design based on the output routing.

20. The system of claim 14, wherein adjusting the shape of the one or more of the first wires comprises determining that a resistance of a second wire of the wires is less than the resistance of the first wire, and adjusting the shape of the second wire to increase the resistance of the second wire by including a non-linear portion within the second wire.
